(19) United States
(12) Patent Application Publication
(10) Pub. No.: US 2025/0107150 A1
(43) Pub. Date: Mar. 27, 2025

(54) SEMICONDUCTOR DEVICES

(71) Applicant: Samsung Electronics Co., Ltd., Suwon-si (KR)

(72) Inventors: Daesik KIM, Suwon-si (KR); Seonbae KIM, Suwon-si (KR); Taeyong KWON, Suwon-si (KR); Changhee KIM, Suwon-si (KR); Doohyun LEE, Suwon-si (KR); Jaehyun KANG, Suwon-si (KR); Jinyoung PARK, Suwon-si (KR); Hyunho PARK, Suwon-si (KR); Jimin YU, Suwon-si (KR); Jinwook LEE, Suwon-si (KR); Seunghyun HWANG, Suwon-si (KR)

(73) Assignee: Samsung Electronics Co., Ltd., Suwon-si (KR)

(21) Appl. No.: 18/650,292

(22) Filed: Apr. 30, 2024

(30) Foreign Application Priority Data
Sep. 21, 2023 (KR) 10-2023-0126351

(51) Int. Cl. H01L 29/417; H01L 21/285; H01L 29/06; H01L 29/08; H01L 29/40; H01L 29/423; H01L 29/45; H01L 29/66; H01L 29/775

(52) U.S. Cl. CPC H10D 30/6729; H01L 21/28518; H10D 30/014; H10D 30/43; H10D 30/6735; H10D 62/121; H10D 62/151; H10D 64/01; H10D 64/017; H10D 64/62

(57) ABSTRACT

A semiconductor device includes a substrate including an active region, a gate structure on the substrate, a plurality of channel layers on the active region, spaced apart from each other and surrounded by the gate structure, a source/drain region in a region at which the active region is recessed, on at least one side of the gate structure, and connected to the channel layers, and a contact plug partially recessing the source/drain region from an upper surface of the source/drain region, electrically connected to the source/drain region, and including a metal-semiconductor compound layer along a recessed surface of the source/drain region and a contact conductor layer on the metal-semiconductor compound layer, wherein the metal-semiconductor compound layer has a first thickness on a side surface of the contact conductive layer and a second thickness on a bottom surface of the contact plug, the second thickness being smaller than the first thickness.

### CROSS-REFERENCE TO RELATED APPLICATION(S)

This application claims benefit of priority to Korean Patent Application No. 10-2023-0126351 filed on Sep. 21, 2023 in the Korean Intellectual Property Office, the disclosure of which is incorporated herein by reference in its entirety.

### BACKGROUND

The present inventive concepts relate to semiconductor devices.

As demands for high performance, high speed, and/or multifunctionality of a semiconductor device, or the like, increase, a degree of integration of the semiconductor device is increasing. In manufacturing a semiconductor device having a fine pattern in response to the trend for a high degree of integration in semiconductor devices, it is necessary to implement a pattern having a fine width or a fine spacing distance. Additionally, in order to overcome limitations in operating characteristics due to a decrease in a size of a planar metal oxide semiconductor field effect transistor (MOSFET), efforts are being made to develop a semiconductor device including a fin field effect transistor (FinFET) having a three-dimensional channel.

### SUMMARY

Some example embodiments of the present inventive concepts provide semiconductor devices having an improved degree of integration and improved electrical characteristics.

According to an example embodiment of the present inventive concepts, a semiconductor device may include a substrate including an active region extending in a first direction, a gate structure extending in a second direction on the substrate, the second direction intersecting the first direction, a plurality of channel layers on the active region, spaced apart from each other in a third direction, and surrounded by the gate structure, the third direction being perpendicular to an upper surface of the substrate, a source/drain region in a region at which the active region is recessed, on at least one side of the gate structure, and connected to the plurality of channel layers, and a contact plug partially recessing the source/drain region from an upper surface of the source/drain region and electrically connected to the source/drain region, the contact plug including a metal-semiconductor compound layer along a recessed surface of the source/drain region and a contact conductor layer on the metal-semiconductor compound layer, wherein the metal-semiconductor compound layer has a first thickness on a side surface of the contact conductive layer and a second thickness on a bottom surface of the contact plug, the second thickness being smaller than the first thickness.

According to an example embodiment of the present inventive concepts, a semiconductor device may include a substrate including an active region extending in a first direction, a gate structure extending in a second direction on the substrate, the second direction intersecting the first direction, a source/drain region on at least one side of the gate structure, and a contact plug partially recessing the source/drain region from an upper surface of the source/drain region and electrically connected to the source/drain region, the contact plug including a metal-semiconductor compound layer along a recessed surface of the source/drain region and a contact conductor layer on the metal-semiconductor compound layer, wherein the contact plug includes a lower region recessing the source/drain region and an upper region on the lower region, and the lower region has a first width at an upper portion thereof and a second width of a lower portion thereof, the second width being smaller than the first width, and wherein the metal-semiconductor compound layer has a first thickness in the first direction on a side surface of the contact conductive layer and a second thickness on a bottom surface of the contact plug, and the second thickness is equal to or smaller than half of the first thickness.

According to an example embodiment of the present inventive concepts, a semiconductor device may include a substrate including an active region extending in a first direction, a gate structure extending in a second direction on the substrate, the second direction intersecting the first direction, first to third channel layers on the active region, spaced apart from each other in a third direction,, sequentially arranged from top, and surrounded by the gate structure, the third direction being perpendicular to an upper surface of the substrate, a source/drain region in a region at which the active region is recessed, on at least one side of the gate structure, and connected to the first to third channel layers, and a contact plug partially recessing the source/drain region from an upper surface of the source/drain region and electrically connected to the source/drain region, the contact plug including a metal-semiconductor compound layer along a recessed surface of the source/drain region and a contact conductor layer on the metal-semiconductor compound layer, wherein the metal-semiconductor compound layer has different thicknesses on a side surface of the contact conductive layer and on a lower surface of the contact conductive layer, and wherein a lower end of the contact plug is located on a level, lower than a level of a lower surface of the second channel layer.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a plan view illustrating a semiconductor device according to an example embodiment.

FIG. 2 is a cross-sectional view illustrating a semiconductor device according to an example embodiment.

FIG. 3 is a partially enlarged view illustrating a semiconductor device according to an example embodiment.

FIGS. 4 to 7 are cross-sectional views illustrating semiconductor devices according to some example embodiments.

FIG. 8 is a cross-sectional view illustrating a semiconductor device according to an example embodiment.

FIGS. 9A to 9I are views illustrating a process sequence to explain a method of manufacturing a semiconductor device according to an example embodiment.

### DETAILED DESCRIPTION

Hereinafter, some example embodiments of the present inventive concepts will be described with reference to the attached drawings. Hereinafter, it can be understood that terms such as ‘on,’ ‘upper,’ ‘upper portion,’ ‘upper surface,’ ‘below,’ ‘lower,’ ‘lower portion,’ ‘lower surface,’ ‘side surface,’ and the like may be denoted by reference numerals and refer to the drawings, except where otherwise indicated.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

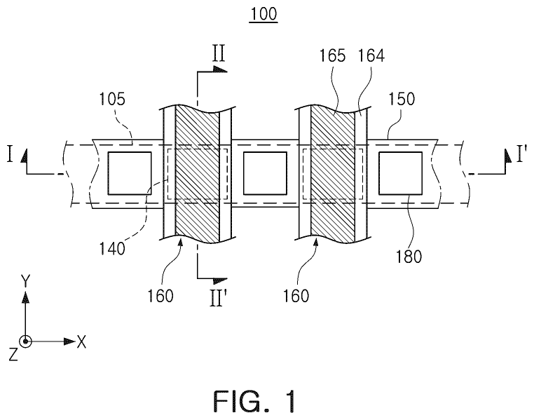

FIG. 1 is a plan view illustrating a semiconductor device according to an example embodiment.

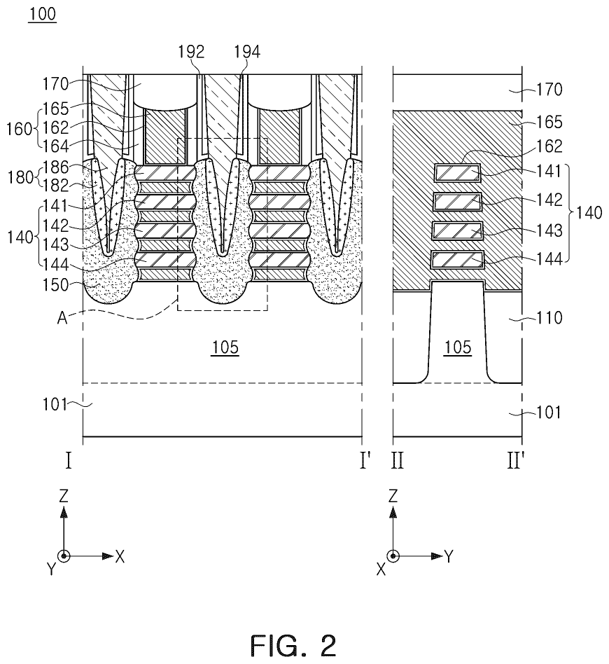

FIG. 2 is a cross-sectional view illustrating a semiconductor device according to an example embodiment. FIG. 2 illustrates cross-sections of the semiconductor device of FIG. 1, taken along lines I-I′ and II-II′. For convenience of explanation, only some components of the semiconductor device will be illustrated in FIG. 1.

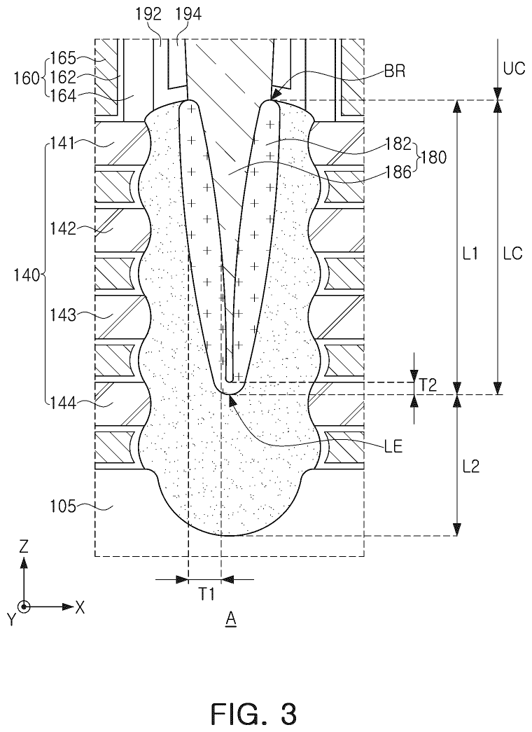

FIG. 3 is a partially enlarged view illustrating a semiconductor device according to an example embodiment. FIG. 3 illustrates an enlarged view of portion ‘A’ in FIG. 2.

Referring to FIGS. 1 to 3, a semiconductor device 100 may include a substrate 101 including an active region 105, channel structures 140 including first to third channel layers 141, 142, 143, and 144 arranged on the active region 105 to be spaced vertically apart from each other, gate structures 160 extending across the active region 105 and each including a gate electrode 165, source/drain regions 150 contacting the channel structures 140, and contact plugs 180 connected to the source/drain regions 150. The semiconductor device 100 may further include a device isolation layer 110, gate capping layers 170, insulating liner layers 192, and contact spacer layers 194.

In the semiconductor device 100, the active region 105 has a fin structure, and the gate electrode 165 may be disposed between the active region 105 and the channel structure 140, between the first to fourth channel layers 141, 142, 143, and 144 of the channel structure 140, and on the channel structure 140. Therefore, the semiconductor device 100 may include transistors having a multi-bridge-channel FET (MBCFET™) structure, which is a gate-all-around type field effect transistor.

The substrate 101 may have an upper surface extending in X and Y-directions. The substrate 101 may include a semiconductor material, such as a group IV semiconductor, a group III-V compound semiconductor, or a group II-VI compound semiconductor. For example, the group IV semiconductor may include silicon, germanium, or silicon-germanium. The substrate 101 may be provided as a bulk wafer, an epitaxial layer, a silicon-on-insulator (SOI) layer, a semiconductor-on-insulator (SeOI) layer, or the like.

The substrate 101 may include the active regions 105 disposed in an upper portion thereof. The active region 105 may be defined by the device isolation layer 110 in the substrate 101, and may be disposed to extend in a first direction, for example, the X-direction. Depending on an explanation method, it is possible to explain the active region 105 as a separate configuration from the substrate 101. Because the active region 105 may partially protrude onto the device isolation layer 110, an upper surface of the active region 105 may be located on a level higher than an upper surface of the device isolation layer 110. The active region 105 may be formed of a portion of the substrate 101, or may include an epitaxial layer grown from the substrate 101. On both sides of the gate structure 160, the active region 105 may be partially recessed to form recess regions, and the source/drain regions 150 may be disposed in the recess regions.

In some example embodiments, the active region 105 may or may not include a well region containing impurities. For example, in a p-type transistor (pFET), the well region may include n-type impurities such as phosphorus (P), arsenic (As), or antimony (Sb). In an n-type transistor (nFET), the well region may include p-type impurities such as boron (B), gallium (Ga), or indium (In). For example, the well region may be located at a desired (or alternatively, predetermined) depth from the upper surface of the active region 105.

The device isolation layer 110 may define the active region 105 in the substrate 101. For example, the device isolation layer 110 may be formed by a shallow trench isolation (STI) process. The device isolation layer 110 may expose the upper surface of the active region 105, and may partially expose an upper portion of the active region 105. In some example embodiments, the device isolation layer 110 may have a curved upper surface such that the device isolation layer 110 has a higher level, as adjacent to the active region 105. The device isolation layer 110 may be formed of an insulating material. The device isolation layer 110 may be, for example, an oxide, a nitride, or a combination thereof.

The gate structures 160 may be arranged on the active region 105 and the channel structures 140, to intersect the active region 105 and the channel structures 140 and extend in a second direction, for example, the Y-direction. Functional channel regions of transistors may be formed in the active region 105 and/or the channel structures 140 that intersect the gate electrodes 165 of the gate structures 160. Each of the gate structures 160 may include a gate electrode 165, gate dielectric layers 162 between the gate electrode 165 and the first to fourth channel layers 141, 142, 143, and 144, and gate spacer layers 164 on side surfaces of the gate electrode 165.

The gate dielectric layers 162 may be disposed between the active region 105 and the gate electrode 165 and between the channel structure 140 and the gate electrode 165, and may cover at least a portion of surfaces of the gate electrode 165. For example, the gate dielectric layers 162 may surround all surfaces except for an uppermost surface of the gate electrode 165. The gate dielectric layers 162 may extend between the gate electrode 165 and the gate spacer layers 164, but example embodiments are not limited thereto. The gate dielectric layer 162 may include an oxide, a nitride, or a high-κ material. The high-κ material may mean a dielectric material having a higher dielectric constant than a silicon oxide (SiO₂). The high-κ material may be, for example, any one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), or praseodymium oxide (Pr₂O₃). According to some example embodiments, the gate dielectric layer 162 may be formed as a multilayer film.

The gate electrode 165 may be disposed to fill a space between the first to fourth channel layers 141, 142, 143, and 144 on the active region 105, and extend onto the channel structure 140. The gate electrode 165 may be spaced apart from the first to fourth channel layers 141, 142, 143, and 144 by the gate dielectric layers 162. The gate electrode 165 may include a conductive material, and may include, for example, metal nitride such as titanium nitride (TiN), tantalum nitride (TaN), or tungsten nitride (WN), and/or a metal material such as aluminum (Al), tungsten (W), molybdenum (Mo), or the like, or a semiconductor material such as doped polysilicon. Depending on some example embodiments, the gate electrode 165 may be formed as two or more multiple layers.

The gate spacer layers 164 may be disposed on both side surfaces of the gate electrode 165 on the channel structure 140 in a cross-section. The gate spacer layers 164 may insulate the source/drain regions 150 and the gate electrodes 165. Depending on some example embodiments, the gate spacer layers 164 may be formed as a multilayer structure. The gate spacer layers 164 may include at least one of an oxide, a nitride, or an oxynitride, and may be formed as, for example, a low-κ film.

The channel structures 140 may be disposed on the active region 105 in regions at which the active region 105 intersects the gate structures 160. Each of the channel structures 140 may include first to fourth channel layers 141, 142, 143, and 144, which may be a plurality of channel layers arranged to be spaced apart from each other in a Z-direction. The first to fourth channel layers 141, 142, 143, and 144 may be sequentially arranged from top, and the first channel layer 141 may be an uppermost channel layer. The channel structures 140 may be connected to the source/drain regions 150. The channel structures 140 may have a width equal to or similar to that of the gate structures 160 in the X-direction, and may have a width equal to or smaller than that of the active region 105 in the Y-direction. In a cross-section in the Y-direction, among the first to fourth channel layers 141, 142, 143, and 144, a channel layer disposed in a lower portion thereof may have a width equal to or greater than a width of a channel layer disposed in an upper portion thereof. The number and shapes of channel layers forming one channel structure 140 may be variously changed according to example embodiments. For example, the channel structure 140 may include three channel layers, may include two channel layers, or may include five or more channel layers.

The channel structures 140 may be formed of a semiconductor material, and may include, for example, at least one of silicon (Si), silicon germanium (SiGe), or germanium (Ge). The channel structures 140 may be formed of, for example, the same material as the active region 105. In some example embodiments, the channel structures 140 may include an impurity region located adjacent to the source/drain regions 150.

The source/drain regions 150 may be disposed in recess regions partially recessing an upper portion of the active region 105 on both sides of the gate structure 160. The recess regions may extend along side surfaces of the channel structures 140 and side surfaces of the gate dielectric layers 162. The source/drain regions 150 may cover side surfaces of each of the first to fourth channel layers 141, 142, 143, and 144 of the channel structures 140 in the X-direction. Upper surfaces of the source/drain regions 150 may be located at a level equal to or higher than lower surfaces of the gate electrodes 165 on the channel structures 140, and the level may be variously changed according to example embodiments. Side surfaces of the source/drain regions 150 may be curved according to the first to fourth channel layers 141, 142, 143, and 144 and the gate structure 160. Specific shapes of the side surfaces of the source/drain regions 150 may be variously changed according to example embodiments.

The source/drain regions 150 may include a semiconductor material, for example, at least one of silicon (Si) or germanium (Ge), and may further include dopants. For example, when the semiconductor device 100 is a pFET, the dopants may be at least one of boron (B), gallium (Ga), or indium (In). The source/drain regions 150 may be formed as an epitaxial layer.

The gate capping layers 170 may be disposed on each of the gate structures 160. The insulating liner layers 192 may cover side surfaces of the gate capping layers 170 and external side surfaces of the gate spacer layers 164, and may be bent to extend onto upper surfaces of the source/drain regions 150. The contact spacer layers 194 may cover side surfaces of the contact plugs 180 on the source/drain regions 150.

The gate capping layers 170, the insulating liner layers 192, and the contact spacer layers 194 may include at least one of an oxide, a nitride, or an oxynitride, respectively. For example, the insulating liner layers 192 may include a material different from that of the contact spacer layers 194, but example embodiments are not limited thereto.

The contact plugs 180 may pass through the contact spacer layers 194 and the insulating liner layers 192 to be connected to the source/drain regions 150, and may apply an electrical signal to the source/drain regions 150. The contact plugs 180 may recess the source/drain regions 150, and may extend into the source/drain regions 150. The contact plugs 180 may extend from top, for example, below a lower surface of the second channel layer 142, which is the second channel layer from the top from among the plurality of channel layers included the channel structure 140, or below a lower surface of the third channel layer 143 as in the present example embodiment. In the present embodiment, lower ends LE of the contact plugs 180 may be located on a level similar to or lower than an upper surface of the fourth channel layer 144.

As illustrated in FIG. 3, the contact plug 180 may include a lower region LC, which corresponds to a recess region of the source/drain region 150, and an upper region UC, which is a region on the source/drain region 150. The upper region UC may have an inclined side surface on which a width of a lower portion is smaller than a width of an upper portion, and may have a shape in which a width decreases substantially continuously. In the lower region LC, the width of the lower portion may be smaller than the width of the upper portion, and the lower region LC may have a shape that is convex in outward and downward directions. The upper region UC and the lower region LC both may have a shape of which a width decreases toward the substrate 101. A bent portion BR may be formed between the upper region UC and the lower region LC as the width changes steeply or discontinuously. The contact plug 180 may be expanded in width in the bent portion BR.

The lower region LC may have a first length L1 from an upper surface of the source/drain region 150 in the Z-direction. The first length L1 may correspond to a depth at which the contact plug 180 recesses the source/drain region 150. The first length L1 may be a length from an upper surface of the source/drain region 150 to the lower end of the contact plug 180. The first length L1 may be equal to or greater than a length from the upper surface of the first channel layer 141 to a lower end LE of the contact plug 180. The first length L1 may be about 10 nm or more, for example, in the range of about 10 nm to about 60 nm. When the first length L1 is smaller than the above range, it may be difficult to secure a contact area between the contact plug 180 and the source/drain region 150, and when the first length L1 is larger than the above range, process difficulty may increase. The first length L1 may be greater than a second length L2 in the Z-direction of a portion of the source/drain region 150 that is not recessed by the contact plug 180. The second length L2 may be a length of the source/drain region 150 below the lower region LC.

The contact plug 180 may include a metal-semiconductor compound layer 182 located in the lower region LC, and a contact conductive layer 186 that fills an internal space of the metal-semiconductor compound layer 182 and forms the upper region UC.

The metal-semiconductor compound layer 182 may be in contact with the source/drain region 150. The metal-semiconductor compound layer 182 may be disposed along a surface on which the source/drain region 150 is recessed. An upper end of the metal-semiconductor compound layer 182 may be located on a level equal to or higher than the upper surface of the first channel layer 141. The upper end of the metal-semiconductor compound layer 182 may be located on a level equal to or higher than the upper surface of the source/drain region 150. The upper end of the metal-semiconductor compound layer 182 may be located in the bent portion BR, and the bent portion BR may be formed along the upper end of the metal-semiconductor compound layer 182. A lower end of the metal-semiconductor compound layer 182 may correspond to the lower end LE of the contact plug 180. The metal-semiconductor compound layer 182 may have an external side surface that is convex in an outward direction and have an internal side surface that is convex in an inward direction.

The metal-semiconductor compound layer 182 may have a non-uniform thickness along a surface of the source/drain region 150. The metal-semiconductor compound layer 182 may have a first thickness T1 on side surfaces of the contact conductive layer 186, and may have a second thickness T2, which is smaller than the first thickness T1, on a bottom surface of the contact plug 180 or a lower surface of the contact conductive layer 186. The first thickness T1 may be a thickness along a direction perpendicular to the side surfaces of the contact conductive layer 186 or may be a thickness along the X-direction. The metal-semiconductor compound layer 182 may have the second thickness T2 in a region forming the lower end LE of the contact plug 180. For example, the second thickness T2 may be equal to or less than half of the first thickness T1. For example, the first thickness T1 may range from about 3 nm to about 10 nm. The first thickness T1 may be a maximum thickness of the metal-semiconductor compound layer 182 along the X-direction or may be a thickness at any point of the metal-semiconductor compound layer 182 on the side surfaces of the contact conductive layer 186. In some example embodiments, the metal-semiconductor compound layer 182 may have a thickness greater than the first thickness T1 at least in regions excluding some upper and lower regions. The metal-semiconductor compound layer 182 may have a shape substantially symmetrical on the left and right sides with respect to a center, in a cross-section in the X-direction.

The contact conductive layer 186 may be disposed on the metal-semiconductor compound layer 182 in the lower region LC to fill a region in which the source/drain region 150 is recessed, and may extend to the upper region UC. The contact conductive layer 186 may have the bent portion BR. The contact conductive layer 186 may have a shape in which, for example, a width decreases linearly in the upper region UC, a width decreases along the bent portion BR, and a width in the lower region LC decreases more steeply as compared to in the upper region UC, toward the substrate 101.

The metal-semiconductor compound layer 182 may include a metal element and a semiconductor element, and may include, for example, at least one of TiSi, CoSi, MoSi, LaSi, NiSi, TaSi, or Wsi. In some example embodiments, the metal-semiconductor compound layer 182 may include germanium (Ge), in addition to or instead of silicon (Si), among the above materials. For example, the contact conductive layer 186 may include a metal material such as tungsten (W), cobalt (Co), molybdenum (Mo), copper (Cu), ruthenium (Ru), aluminum (Al), or the like.

The contact plug 180 of the present example embodiment may secure a contact area by recessing the source/drain region 150 relatively deeply, and may further reduce contact resistance by using the metal-semiconductor compound layer 182. The lower region LC of the contact plug 180 may have a relatively large aspect ratio, for example, in the range of about 0.9 to about 6.0, such that the metal-semiconductor compound layer 182 may be stably formed in a deeply recessed region while having a shape in which a thickness in a lower portion is smaller than a thickness in side portions.

An interconnection structure, such as a contact plug, may be further disposed on the gate electrode 165, and an interconnection structure, such as an interconnection line connected to the contact plugs 180, may be further disposed on the contact plugs 180.

In the description of the following example embodiments, descriptions that overlap those described above with reference to FIGS. 1 to 3 will be omitted.

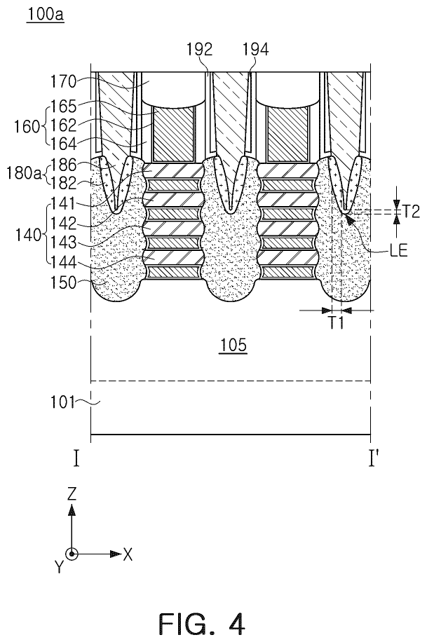

FIGS. 4 to 7 are cross-sectional views illustrating semiconductor devices according to some example embodiments. FIGS. 4 to 7 illustrate a region corresponding to a cross-section of the semiconductor device of FIG. 1, taken along line I-I′.

Referring to FIG. 4, a level of lower ends LE of contact plugs 180a in a semiconductor device 100a may be different from those in the example embodiment of FIG. 2.

The contact plugs 180a may extend from top, for example, below a lower surface of a second channel layer 142 of a channel structure 140, and may extend onto a level higher than an upper surface of a third channel layer 143. In the present example embodiment, the lower ends LE of the contact plugs 180a may be located on a level between the lower surface of the second channel layer 142 and the upper surface of the third channel layer 143. In some example embodiments, the lower ends LE of the contact plugs 180a may be changed within the range of being located at a level lower than the lower surface of the second channel layer 142. In the present example embodiment, a first thickness T1 of side portions of a metal-semiconductor compound layer 182 may be greater than a second thickness T2 of a lower portion of the metal-semiconductor compound layer 182.

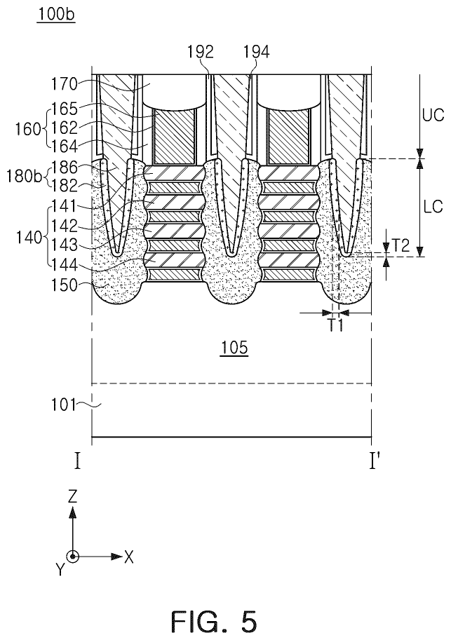

Referring to FIG. 5, in a semiconductor device 100b, a metal-semiconductor compound layer 182 of contact plugs 180b may have both external and internal side surfaces that are convex in an outward direction. Curves of the external side surface and the internal side surface may have shapes corresponding to each other, or may have different shapes.

Therefore, a contact conductive layer 186 may extend from an upper region UC to a lower region LC, and may have a shape of which a width gently decreases, as compared to the example embodiment of FIG. 2. For example, while the contact conductive layer 186 of the example embodiment of FIG. 2 has a funnel shape or a similar shape in the lower region LC, the contact conductive layer 186 of the present example embodiment may have a streamlined shape or a similar shape in the lower region LC. In example embodiments, shapes of the metal-semiconductor compound layer 182 and the contact conductive layer 186 may be changed in various manners. In the present example embodiment, a first thickness T1 of side portions of the metal-semiconductor compound layer 182 may be greater than a second thickness T2 of a lower portion of the metal-semiconductor compound layer 182.

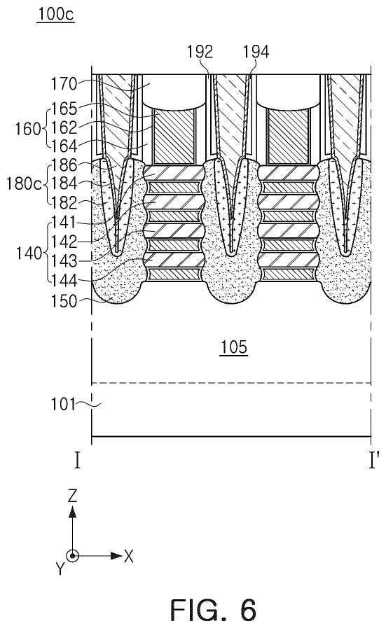

Referring to FIG. 6, in a semiconductor device 100c, contact plugs 180c may further include a barrier layer 184 disposed between a metal-semiconductor compound layer 182 and a contact conductive layer 186.

The barrier layer 184 may be interposed between the metal-semiconductor compound layer 182 and the contact conductive layer 186 in a lower region LC, and may surround a side surface of the contact conductive layer 186 in an upper region UC. The barrier layer 184 may include, for example, a metal nitride such as titanium nitride (TiN), tantalum nitride (TaN), or tungsten nitride (WN), or may include a metal such as titanium (Ti), cobalt (Co), molybdenum (Mo), or platinum (Pt). In example embodiments, the number and arrangement of conductive layers constituting the contact plugs 180c may be changed.

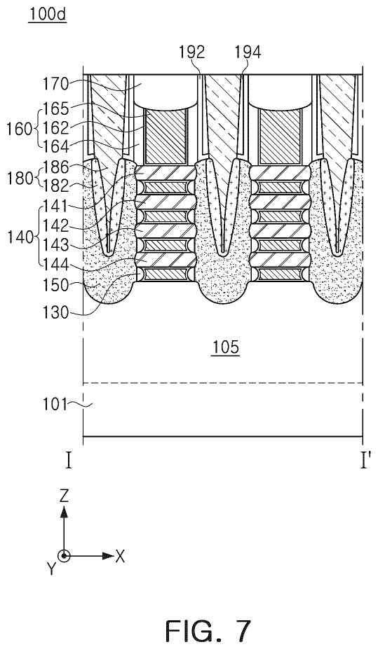

Referring to FIG. 7, a semiconductor device 100d may further include internal spacer layers 130 disposed between gate structures 160 and source/drain regions 150.

The internal spacer layers 130 may be disposed parallel to a gate electrode 165 between first to fourth channel layers 141, 142, 143, and 144 in the Z-direction. The gate electrode 165 may be stably spaced apart and electrically separated from the source/drain regions 150 by the internal spacer layers 130. The internal spacer layers 130 may have a shape in which a side surface facing the gate electrode 165 may be convexly rounded inward toward the gate electrode 165, but example embodiments are not limited thereto. The internal spacer layers 130 may include at least one of an oxide, a nitride, or an oxynitride, and may be formed of, for example, a low-κ film. Such a semiconductor device 100d may be additionally disposed in a region of semiconductor devices of other example embodiments.

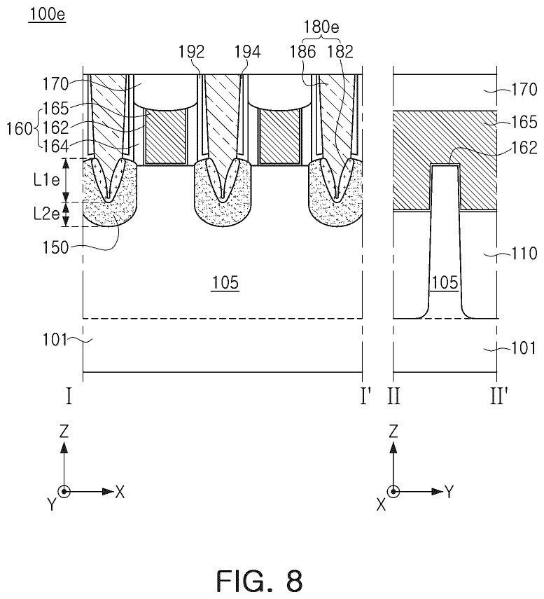

FIG. 8 is a cross-sectional view illustrating a semiconductor device according to an example embodiment. FIG. 8 illustrates a region corresponding to FIG. 2.

Referring to FIG. 8, unlike the embodiment of FIGS. 1 to 3, a semiconductor device 100e may not include channel structures 140, and accordingly, arrangement of gate structures 160 may be different from the above example embodiments. The semiconductor device 100e may include FinFETs that do not include a separate channel layer.

In the semiconductor device 100e, channel regions of transistors may be located to be limited to an active region 105 having a fin structure, which may be an active structure. Additionally, separate channel layers may not be interposed in gate electrodes 165. Therefore, source/drain regions 150 may not have a curved shape on side surfaces corresponding to the gate structure 160 and the channel layers. A depth L1e at which contact plugs 180e recess the source/drain regions 150 may be greater than a length L2e of non-recess regions of the source/drain regions 150 in the Z-direction. The recess depth L1e may be, for example, about 10 nm or more.

In addition, the description of the structure of the contact plugs 180e and the like in the example embodiments of FIGS. 1 to 3 may be applied in the same manner. Such a semiconductor device 100e may be additionally disposed in a region of semiconductor devices of other example embodiments.

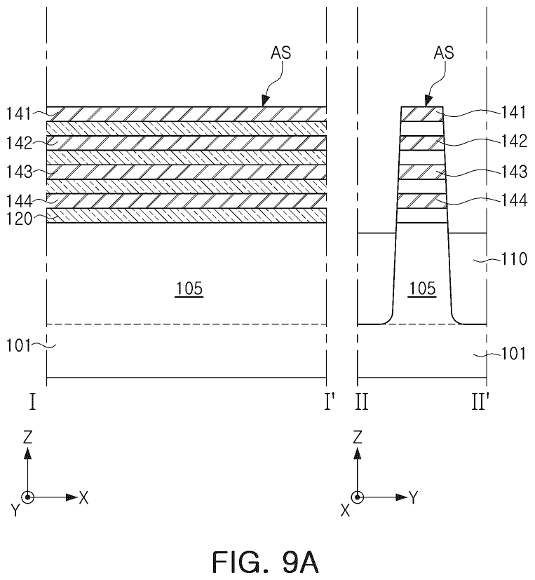

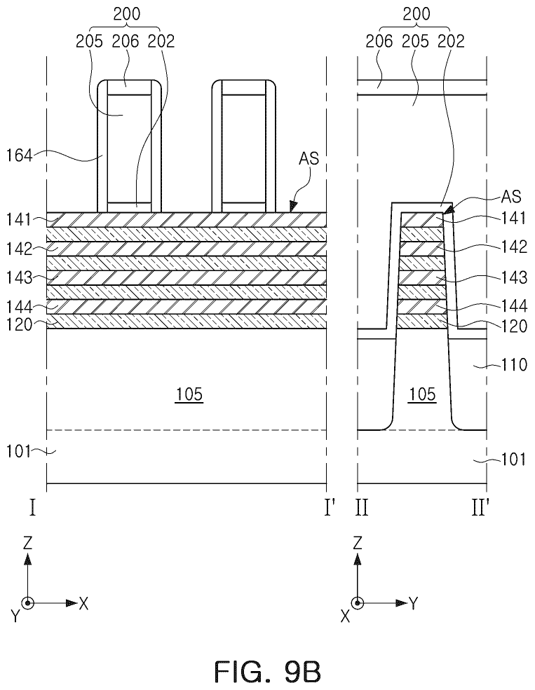

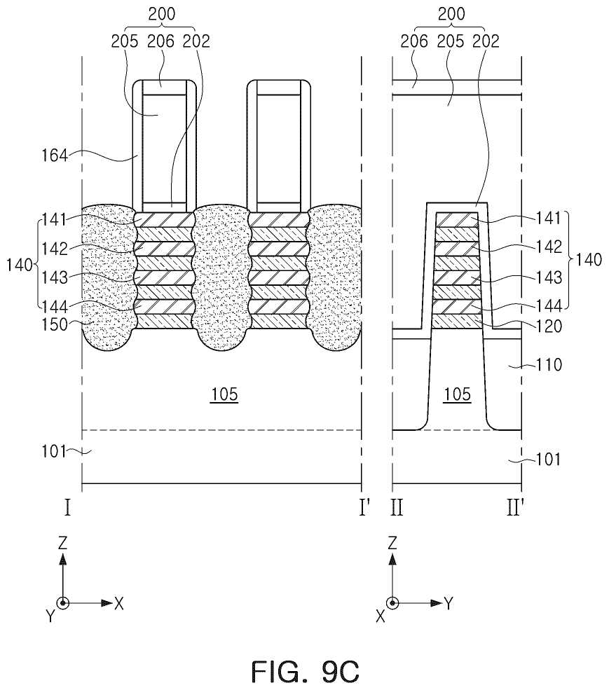

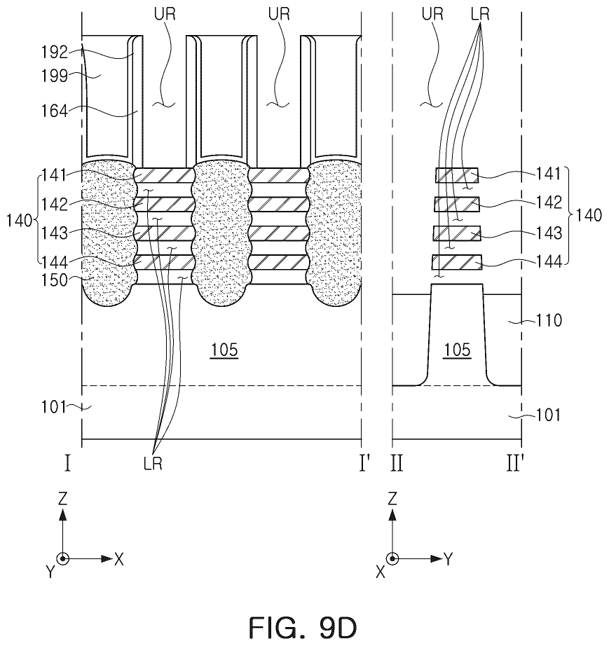

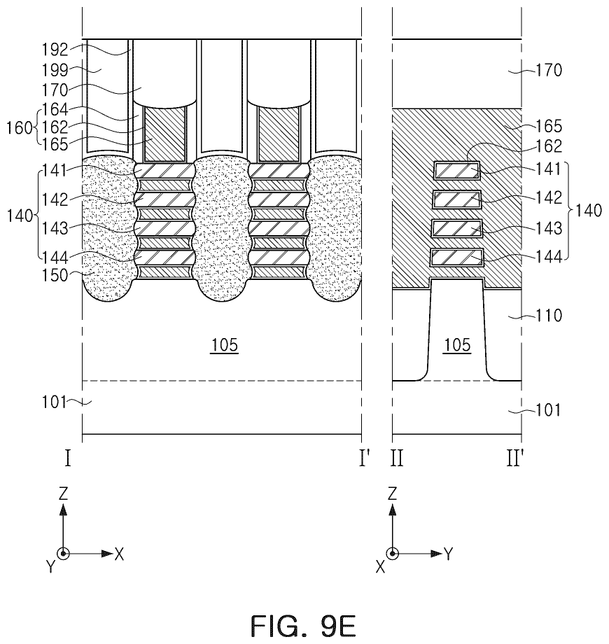

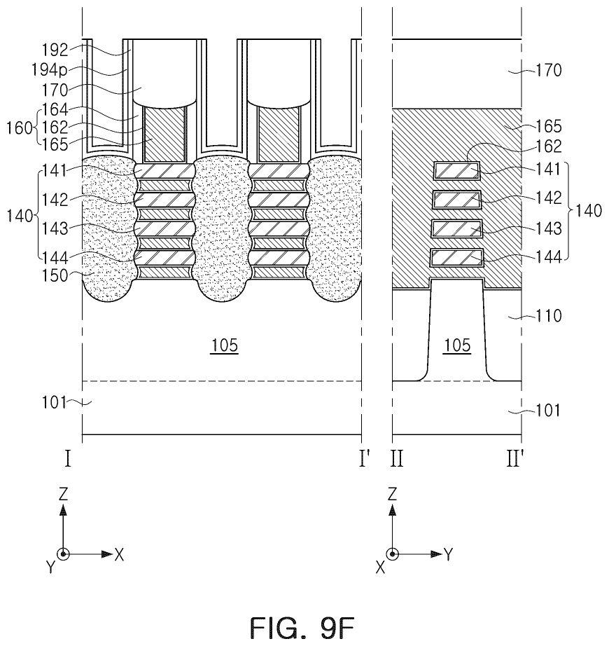

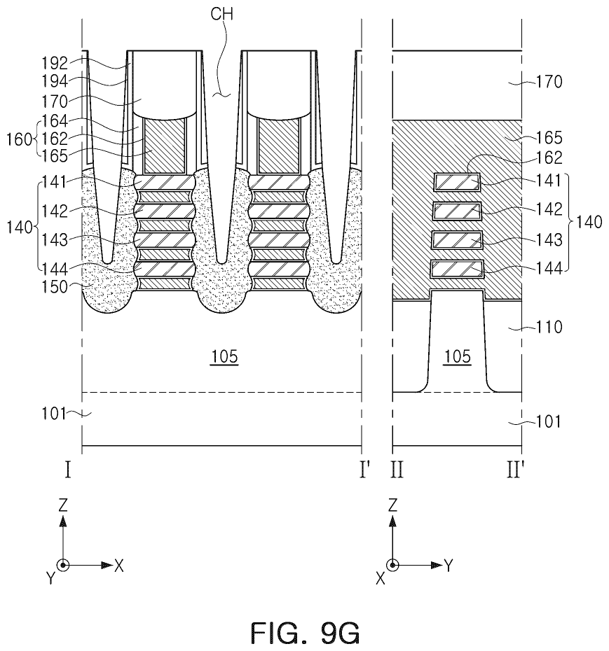

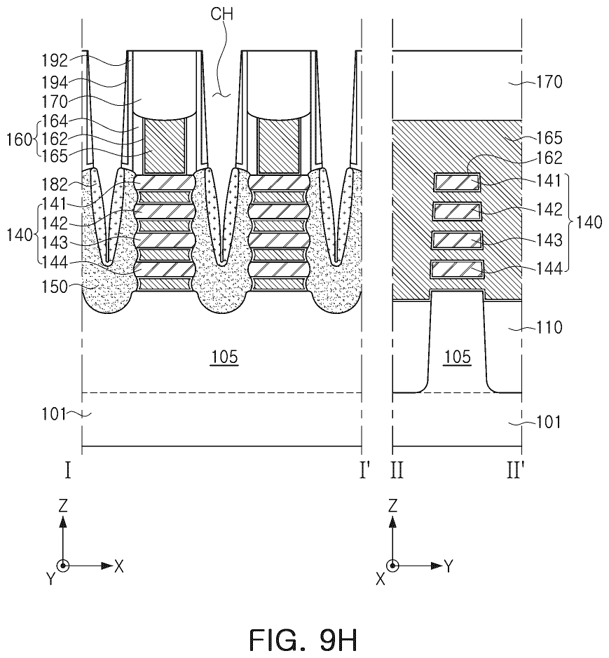

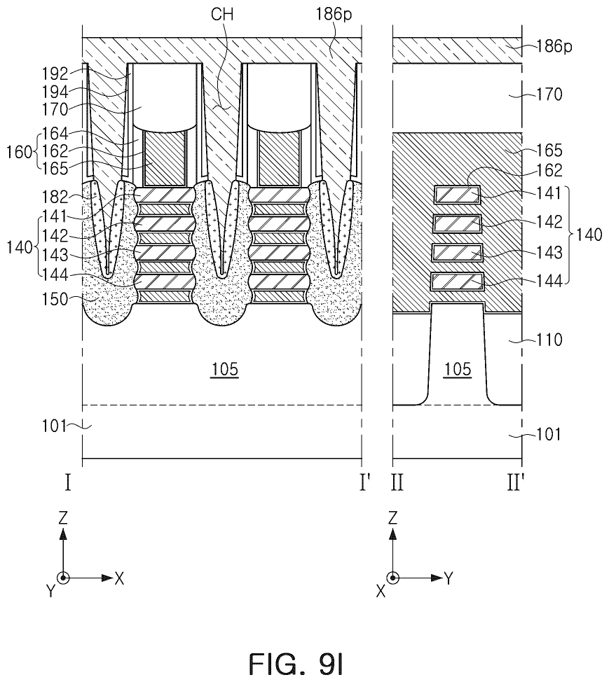

FIGS. 9A to 9I are views illustrating a process sequence to explain a method of manufacturing a semiconductor device according to an example embodiment. FIGS. 9A to 9I illustrate an example of a method of manufacturing the semiconductor device of FIG. 2.

Referring to FIG. 9A, sacrificial layers 120 and first to fourth channel layers 141, 142, 143, and 144 may be alternately stacked on a substrate 101, the sacrificial layers 120, the first to fourth channel layers 141, 142, 143, and 144, and the substrate 101 may be partially removed to form an active structure AS including an active region 105, and then a device isolation layer 110 may be formed.

The sacrificial layers 120 may be a layer that may be replaced with gate dielectric layers 162 and gate electrodes 165 below the first channel layer 141 by a subsequent process, as illustrated in FIG. 2. The sacrificial layers 120 may be formed of a material having etch selectivity with respect to the first to fourth channel layers 141, 142, 143, and 144, respectively. The first to fourth channel layers 141, 142, 143, and 144 may include a material different from the sacrificial layers 120. The sacrificial layers 120 and the first to fourth channel layers 141, 142, 143, and 144 may include, for example, a semiconductor material including at least one of silicon (Si), silicon germanium (SiGe), or germanium (Ge), but may include different materials, and may or may not include impurities. For example, the sacrificial layers 120 may include silicon germanium (SiGe), and the first to fourth channel layers 141, 142, 143, and 144 may include silicon (Si).

The sacrificial layers 120 and the first to fourth channel layers 141, 142, 143, and 144 may be alternately stacked by performing an epitaxial growth process. The number of sacrificial layers 120 and the number of channel layers, alternately stacked, may be changed in various example embodiments.

The active structure AS may include the active region 105, the sacrificial layers 120, and the first to fourth channel layers 141, 142, 143, and 144. The active structure AS may be formed in a linear shape extending in one direction, for example, the X-direction, and may be formed to be spaced apart from adjacent active structures in the Y-direction. Side surfaces of the active structure AS in the Y-direction may be coplanar with each other, and may be located on a straight line.

After filling a region from which the active region 105, the sacrificial layers 120, and the first to fourth channel layers 141, 142, 143, and 144 are partially removed with an insulating material, the insulating material may be partially removed to protrude the active region 105, to form the device isolation layer 110. An upper surface of the device isolation layer 110 may be formed to be lower than an upper surface of the active region 105.

Referring to FIG. 9B, sacrificial gate structures 200 and gate spacer layers 164 may be formed on the active structure AS.

Each of the sacrificial gate structures 200 may be a sacrificial structure formed in a region in which the gate dielectric layers 162 and the gate electrode 165 are to be disposed on the channel structure 140 in a subsequent process as illustrated in FIG. 2. The sacrificial gate structures 200 may have a linear shape extending in a direction intersecting the active structure. The sacrificial gate structures 200 may extend, for example, in the Y-direction. Each of the sacrificial gate structures 200 may include first and second sacrificial gate layers 202 and 205 and a mask pattern layer 206, sequentially stacked. The first and second sacrificial gate layers 202 and 205 may be patterned using the mask pattern layer 206.

The first and second sacrificial gate layers 202 and 205 may be an insulating layer and a conductive layer, respectively, but are not limited thereto, and the first and second sacrificial gate layers 202 and 205 may be formed as a single layer. For example, the first sacrificial gate layer 202 may include silicon oxide, and the second sacrificial gate layer 205 may include polysilicon. The mask pattern layer 206 may include silicon oxide and/or silicon nitride.

The gate spacer layers 164 may be formed on both side walls of the sacrificial gate structures 200. The gate spacer layers 164 may be formed of a low-material, and may include, for example, at least one of SiO, SiN, SiCN, SiOC, SiON, or SiOCN.

Referring to FIG. 9C, a portion of the active structure AS exposed from the sacrificial gate structures 200 may be removed to form recess regions, and source/drain regions 150 may be formed in the recess regions.

Using the sacrificial gate structures 200 and the gate spacer layers 164 as masks, exposed portions of the sacrificial layers 120 and the first to fourth channel layers 141, 142, 143, and 144 may be removed to form recess regions RC. Thus, the first to fourth channel layers 141, 142, 143, and 144 may form channel structures 140 having a limited length in the X-direction.

The source/drain regions 150 may be formed in the recess regions, and may be grown from side surfaces of the active regions 105 and the channel structures 140, for example, by a selective epitaxial process. The source/drain regions 150 may contain impurities by in-situ doping, and may include a plurality of layers having different doping elements and/or doping concentrations.

In the example embodiment of FIG. 7, the semiconductor device may be manufactured by removing a portion of the sacrificial layers 120 exposed through the recess regions and forming internal spacer layers 130 on side surfaces of the sacrificial layers 120, before forming the source/drain regions 150 in the present operation.

Referring to FIG. 9D, insulating liner layers 192 and interlayer insulating layers 199 may be formed, and the sacrificial gate structures 200 and the sacrificial layers 120 may be removed.

The insulating liner layers 192 may be formed to extend along side surfaces of the sacrificial gate structures 200 and upper surfaces of the source/drain regions 150. The insulating liner layers 192 may include a material, which is relatively hard and has a low dielectric constant. For example, the insulating liner layers 192 may include a material harder than the interlayer insulating layer 199, and may include, for example, SiCN. The interlayer insulating layer 199 may be formed to fill a space between the sacrificial gate structures 200 on the insulating liner layers 192. The insulating liner layers 192 and the interlayer insulating layer 199 may be formed to expose the mask pattern layers 206 by a planarization process.

The sacrificial gate structures 200 and the sacrificial layers 120 may be removed selectively with respect to the gate spacer layers 164, the insulating liner layers 192, and the channel structures 140. First, the sacrificial gate structures 200 may be removed to form upper gap regions UR, and then the sacrificial layers 120 exposed through the upper gap regions UR may be removed to form lower gap regions LR. For example, when the sacrificial layers 120 include silicon germanium (SiGe) and the channel structures 140 include silicon (Si), the sacrificial layers 120 may be removed selectively with respect to the channel structures 140 by a wet etching process.

Referring to FIG. 9E, gate structures 160 and gate capping layers 170 may be formed.

The gate structures 160 may be formed to fill the upper gap regions UR and the lower gap regions LR. Gate dielectric layers 162 may be formed to conformally cover internal surfaces of the upper gap regions UR and lower gap regions LR. A gate electrode 165 may be formed to completely fill the upper gap regions UR and the lower gap regions LR, and may be then removed from the upper gap regions UR from top, together with the gate dielectric layers 162 and the gate spacer layers 164, to have a certain depth. Thus, the gate structures 160 each including the gate dielectric layer 162, the gate electrode 165, and the gate spacer layer 164 may be formed.

The gate capping layers 170 may be formed by filling regions from which the gate electrode 165, the gate dielectric layers 162, and the gate spacer layers 164 are removed with an insulating material, and performing a planarization process. Relative thicknesses and shapes of lower surfaces of the gate capping layers 170 may be changed in various example embodiments.

Referring to FIG. 9F, the interlayer insulating layer 199 may be at least partially removed, and preliminary contact spacer layers 194p may be formed.

The interlayer insulating layer 199 may be partially or completely removed by an etching process in a region in which contact plugs 180 (see FIG. 2) are to be formed. During the removal process of the interlayer insulating layer 199, the source/drain regions 150 may be protected by the insulating liner layers 192. The preliminary contact spacer layers 194p may be formed conformally along the insulating liner layers 192 in a region in which the interlayer insulating layer 199 has been removed. The preliminary contact spacer layers 194p may include, for example, at least one of SiO, SiN, SiCN, SiOC, SiON, or SiOCN.

Referring to FIG. 9G, the preliminary contact spacer layers 194p, the insulating liner layers 192, and the source/drain regions 150 may be partially removed respectively to form contact holes CH.

The contact holes CH may be formed by sequentially etching the preliminary contact spacer layers 194p and the insulating liner layers 192 from top in a region in which the contact plugs 180 (see FIG. 2) are to be formed, and recessing the source/drain regions 150 from an upper surface thereof. By the present operation, contact spacer layers 194 may be formed. When forming the contact holes CH, sizes of the contact holes CH may be easily controlled by the preliminary contact spacer layers 194p and the insulating liner layers 192, and an increase in widths of the contact holes CH may be mitigated or prevented.

Referring to FIG. 9H, metal-semiconductor compound layers 182 may be formed in a region including lower ends of the contact holes CH.

The metal-semiconductor compound layers 182 may be formed by allowing a metal layer to react with the source/drain regions 150 while depositing the metal layer at a relatively high temperature, for example, about 400° C. to about 500° C. The metal-semiconductor compound layers 182 may be formed to include some of materials of the source/drain regions 150 exposed by the contact holes CH, and may be formed in an expanded form centered around boundaries of the contact holes CH.

Because the contact holes CH have a relatively large aspect ratio, during the etching process for forming the contact holes CH, some impurities may remain or some of the source/drain regions 150 may be oxidized on bottom surfaces of the contact holes CH. Thus, the metal-semiconductor compound layers 182 may be formed to have a relatively small thickness on the bottom surfaces of the contact holes CH, as compared to an internal side walls of the contact holes CH.

Referring to FIG. 9I, a preliminary contact conductive layer 186p may be formed.

The preliminary contact conductive layer 186p may be formed to fill the contact holes CH on the metal-semiconductor compound layers 182. The preliminary contact conductive layer 186p may be formed to extend onto the gate capping layers 170.

Next, referring to FIG. 2, the preliminary contact conductive layer 186p may be partially removed to form a contact conductive layer 186.

Contact plugs 180 may be formed by partially removing the preliminary contact conductive layer 186p from an upper surface thereof using an etching process and/or a planarization process to form contact conductive layers 186 separated from each other. In the present operation, the gate capping layers 170 may also be partially removed to have a reduced height. Thus, the semiconductor device 100 of FIGS. 1 to 3 may be manufactured.

A structure of a contact plug connected to a source/drain region may provide a semiconductor device having an improved degree of integration and improved electrical characteristics.

Various advantages and effects of the present inventive concepts are not limited to the above-described contents, and may be more easily understood through description of specific example embodiments of the present inventive concepts.

While some example embodiments have been illustrated and described above, it will be apparent to those skilled in the art that modifications and variations could be made without departing from the scope of the present inventive concepts as defined by the appended claims.

What is claimed is:

1. A semiconductor device comprising:
a substrate including an active region extending in a first direction;
a gate structure extending in a second direction on the substrate, the second direction intersecting the first direction;
a plurality of channel layers on the active region, spaced apart from each other in a third direction, and surrounded by the gate structure, the third direction being perpendicular to an upper surface of the substrate;
a source/drain region in a region at which the active region is recessed, on at least one side of the gate structure, and connected to the plurality of channel layers; and
a contact plug partially recessing the source/drain region from an upper surface of the source/drain region and electrically connected to the source/drain region, the contact plug including a metal-semiconductor compound layer along a recessed surface of the source/drain region and a contact conductor layer on the metal-semiconductor compound layer,
wherein the metal-semiconductor compound layer has a first thickness on a side surface of the contact conductive layer and a second thickness on a bottom surface of the contact plug, the second thickness being smaller than the first thickness.

2. The semiconductor device of claim 1, wherein the second thickness is equal to or smaller than half of the first thickness.

3. The semiconductor device of claim 2, wherein the first thickness ranges from about 3 nm to about 10 nm.

4. The semiconductor device of claim 1, wherein
the plurality of channel layers comprise first to third channel layers sequentially arranged in the third direction, and
a level of a lower end of the contact plug is lower than a lower surface of the second channel layer.

5. The semiconductor device of claim 4, wherein the level of the lower end of the contact plug is between the lower surface of the second channel layer and an upper surface of the third channel layer.

6. The semiconductor device of claim 1, wherein a length from the upper surface of the source/drain region to a lower end of the contact plug ranges from about 10 nm to about 60 nm.

7. The semiconductor device of claim 1, wherein
the contact plug comprises a lower region recessing the source/drain region and an upper region on the lower region, and
each of the lower region and the upper region has a first width at a lower portion thereof and a second width at an upper portion thereof, the first width being smaller than the second width.

8. The semiconductor device of claim 7, wherein the contact plug has a bent portion between the lower region and the upper region, the bent portion being a portion at which a width of the contact plug is discontinuously changed.

9. The semiconductor device of claim 7, wherein, in the lower region, a width of the contact conductive layer decreases toward the substrate.

10. The semiconductor device of claim 1, wherein the contact plug further comprises a barrier layer between the metal-semiconductor compound layer and the contact conductive layer and extending along the side surface of the contact conductive layer.

11. The semiconductor device of claim 1, further comprising:
a gate capping layer on the gate structure; and
a contact spacer layer between the gate capping layer and the contact plug.

12. The semiconductor device of claim 1, wherein a level of an upper end of the metal-semiconductor compound layer is equal to or higher than an upper surface of an uppermost one of the plurality of channel layers.

13. A semiconductor device comprising:
a substrate including an active region extending in a first direction;
a gate structure extending in a second direction on the substrate, the second direction intersecting the first direction;
a source/drain region on at least one side of the gate structure; and
a contact plug partially recessing the source/drain region from an upper surface of the source/drain region and electrically connected to the source/drain region, the contact plug including a metal-semiconductor compound layer along a recessed surface of the source/drain region and a contact conductor layer on the metal-semiconductor compound layer,
wherein the contact plug includes a lower region recessing the source/drain region and an upper region on the lower region, and the lower region has a first width at an upper portion thereof and a second width at a lower portion thereof, the second width being smaller than the first width, and
wherein the metal-semiconductor compound layer has a first thickness in the first direction on a side surface of the contact conductive layer and a second thickness on a bottom surface of the contact plug, and the second thickness is equal to or smaller than half of the first thickness.

14. The semiconductor device of claim 13, wherein the, in a third direction perpendicular to an upper surface of the substrate, a length of the lower region is greater than a length of the source/drain region below the lower region.

15. The semiconductor device of claim 13, wherein a length of the lower region is about 10 nm or more.

16. The semiconductor device of claim 13, wherein a level of an upper end of the metal-semiconductor compound layer is equal to or higher than the upper surface of the source/drain region.

17. A semiconductor device comprising:
a substrate including an active region extending in a first direction;
a gate structure extending in a second direction on the substrate, the second direction intersecting the first direction;
first to third channel layers on the active region, spaced apart from each other in a third direction, sequentially arranged from top, and surrounded by the gate structure, the third direction being perpendicular to an upper surface of the substrate;
a source/drain region in a region at which the active region is recessed, on at least one side of the gate structure, and connected to the first to third channel layers; and
a contact plug partially recessing the source/drain region from an upper surface of the source/drain region and electrically connected to the source/drain region, the contact plug including a metal-semiconductor compound layer along a recessed surface of the source/drain region and a contact conductor layer on the metal-semiconductor compound layer,
wherein the metal-semiconductor compound layer has different thicknesses on a side surface of the contact conductive layer and on a lower surface of the contact conductive layer, and
wherein a level of a lower end of the contact plug is lower than a level of a lower surface of the second channel layer.

18. The semiconductor device of claim 17, wherein a lower portion of the contact plug recessing the source/drain region comprises a region having a width decreasing toward the substrate.

19. The semiconductor device of claim 17, wherein the contact conductive layer has a bent portion along an upper end of the metal-semiconductor compound layer.

20. The semiconductor device of claim 17, wherein the metal-semiconductor compound layer has a first thickness on the side surface of the contact conductive layer and a second thickness on the lower surface of the contact conductive layer, the second thickness being smaller than the first thickness.
